(19) United States
(12) Patent Application Publication
(10) Pub. No.: US 2024/0429334 A1
(43) Pub. Date: Dec. 26, 2024

(54) FLEXIBLE CRYSTALLINE SILICON PHOTOVOLTAIC MODULE AND MANUFACTURING METHOD THEREFOR

(71) Applicant: OPES SOLUTIONS (CHANGZHOU) CO., LTD. - FACTORY, Jiangsu (CN)

(72) Inventors: Robert Christoph HÄNDEL, Icking (DE); Hong-Shiang TANG, Taoyuan City, Taiwan (CN); Fan-Wei HSU, Minxiong Township, Taiwan (CN); Yen-Chuan CHEN, Zhudong Township, Taiwan (CN)

(21) Appl. No.: 18/689,726

(22) PCT Filed: Dec. 10, 2021
(86) PCT No.: PCT/IB2021/061563

§ 371 Date: Mar. 6, 2024

(30) Foreign Application Priority Data
Sep. 10, 2021 (CN) 202111063571.6

(51) Int. Cl. H01L 31/048; H01L 31/18

(52) U.S. Cl. CPC H01L 31/0481; H01L 31/1804

(57) ABSTRACT

The present invention provides a flexible crystalline silicon photovoltaic module and a manufacturing method therefor. The flexible crystalline silicon photovoltaic module comprises a front panel, a rear panel, an encapsulation layer and a solar cell array; the front panel and the rear panel are respectively arranged outside the encapsulation layer, on which an upper surface and a lower surface of the solar cell array are laminated; and ionomer interlayer films are arranged between the encapsulation layer and the solar cell array. The manufacturing method for the flexible crystalline silicon photovoltaic module comprises the following steps: connecting a plurality of solar cells in series to form a solar cell array; stacking the front panel, the encapsulation layer and the ionomer interlayer film in turn from bottom to top, placing the solar cell array on the ionomer interlayer film, placing the ionomer interlayer film and the encapsulation layer, and finally placing the rear panel; putting stacked parts into a laminator with a lamination temperature of 140-150° C., a vacuuming time of 6-7 min, a downward pressure of −10 to −30 kPa and a time delay of 700-900 s to complete the hot laminating process. The photovoltaic module of the present invention reveals good bending resistance.

### FIELD OF THE INVENTION

The present invention relates to a photovoltaic module and a manufacturing method therefor, and belongs to the technical field of photovoltaics.

### BACKGROUND OF THE INVENTION

Existing traditional flexible crystalline silicon solar photovoltaic modules are mainly based on transparent polymeric plastic films, and include a transparent PET polymer front panel and a PET polymer rear panel; in which the solar cell array is encapsulated with EVA and polyvinyl acetate by hot pressing. Despite a little flexibility and light weight, such modules show poor mechanical strength, and do not provide flexibility like thin-film photovoltaic modules after being bent and stressed. Moreover, the hard and brittle characteristics of crystalline silicon cells cause the solar cells inside the modules to crack and be damaged, which permanently reduces the output power.

### SUMMARY OF THE INVENTION

The present invention intends to provide a flexible crystalline silicon photovoltaic module with bending resistance and a manufacturing method therefor.

To achieve the purpose, the technical solution of the present invention is to provide a flexible crystalline silicon photovoltaic module, which includes a front panel, a rear panel, an encapsulation layer and a solar cell array; the front panel and the rear panel are respectively arranged outside the encapsulation layer, on which an upper surface and a lower surface of the solar cell array are laminated. At least one ionomer interlayer film is arranged between the encapsulation layer and the solar cell array.

Ionomers are beside polyelectrolytes one type of ionic polymers. Ionomers can be synthesized through copolymerization of a polar monomer and a non-polar monomer building ionic connections. These ionic connections are strong bindings giving typical characteristics to the ionomer. Between the polymer chains metal-ions act as physically crosslinking points. Ionomers can be classified in the group of thermoplastics. Interlayer films produced of ionomers show a high stiffness over a wide temperature range and a very high transparency. The ionomer interlayer films are characterized by glassy state at normal temperature and high shearing modulus.

Ionomer interlayer films are commercialized e.g. under product names SentryGlas® (SG) or SentryGlas® plus (SGP). Ionomer interlayer films are around five times harder and 100 times stiffer than conventional interlayer films made of PVB. Typical values of the shear modulus G and the Young's modules E and further characteristics for ionomer interlayer films are shown in the following tables. The tables show typical values for SentryGlas® as given in the datasheet taken from www.sentryglas.com (Document Ref. GLS-TECBU-2014-11).

shear modulus G [MPa]

| | load duration | | | | | | |
|---|---|---|---|---|---|---|---|
| temperature | 1 s | 3 s | 1 min | 1 hr | 1 day | 1 mo | 10 yrs |
| 10° C. | 240. | 236. | 225. | 206. | 190. | 171. | 153. |
| 20° C. | 217. | 211. | 195. | 169. | 146. | 112. | 86.6 |
| 24° C. | 200. | 193. | 173. | 142. | 111. | 73.2 | 43.3 |
| 30° C. | 151. | 141. | 110. | 59.9 | 49.7 | 11.6 | 5.31 |
| 40° C. | 77.0 | 63.0 | 30.7 | 9.28 | 4.54 | 3.29 | 2.95 |
| 50° C. | 36.2 | 26.4 | 11.3 | 4.20 | 2.82 | 2.18 | 2.00 |
| 60° C. | 11.8 | 8.18 | 3.64 | 1.70 | 1.29 | 1.08 | 0.97 |
| 70° C. | 3.77 | 2.93 | 1.88 | 0.84 | 0.59 | 0.48 | 0.45 |
| 80° C. | 1.55 | 1.32 | 0.83 | 0.32 | 0.25 | 0.21 | 0.18 |

Young's modulus E [MPa]

| | load duration | | | | | | |
|---|---|---|---|---|---|---|---|
| temperature | 1 s | 3 s | 1 min | 1 hr | 1 day | 1 mo | 10 yrs |
| 10° C. | 692. | 681. | 651. | 597. | 553. | 499. | 448. |
| 20° C. | 628. | 612. | 567. | 493. | 428. | 330. | 256. |
| 24° C. | 581. | 561. | 505. | 416. | 327. | 217. | 129. |
| 30° C. | 442. | 413. | 324. | 178. | 148. | 34.7 | 15.9 |
| 40° C. | 228. | 187. | 91.6 | 27.8 | 13.6 | 9.86 | 8.84 |
| 50° C. | 108. | 78.8 | 33.8 | 12.6 | 8.45 | 6.54 | 6.00 |
| 60° C. | 35.3 | 24.5 | 10.9 | 5.10 | 3.87 | 3.24 | 2.91 |
| 70° C. | 11.3 | 8.78 | 5.64 | 2.52 | 1.77 | 1.44 | 1.35 |
| 80° C. | 4.65 | 3.96 | 2.49 | 0.96 | 0.75 | 0.63 | 0.54 |

| Property | Unit | Value | ASTM Test |
|---|---|---|---|
| Young's Modulus | Mpa | 300 | D5026 |
| Tear Strength | MJ/m3 | 50 | D638 |
| Tensile Strength | MPa | 34.5 | D638 |
| Elongation | % | 400 | D638 |
| Density | g/cm3 | 0.95 | D792 |
| Flex Modulus @ 23° C. | MPa | 345 | D790 |
| Heat deflection Temperature @ 0.46 MPa | ° C. | 43 | D648 |
| Melting Point | ° C. | 94 | (DSC) |
| Coeff. of Thermal Expansion (−20° C. to 32° C.) | 10−3 cm/cm ° C. | 10-15 | D696 |
| Thermal Conductivity | W/M-K | | |

The invention is not limited to ionomer interlayer films having characteristices as given in the tables above. The invention also includes ionomer interlayer films having shear modulus and Young's modulus and further characteristics in a range+/−5%, preferably +/−2.5%, from the values inside the tables.

The following figure shows an example of the chemical structure of an ionomer.

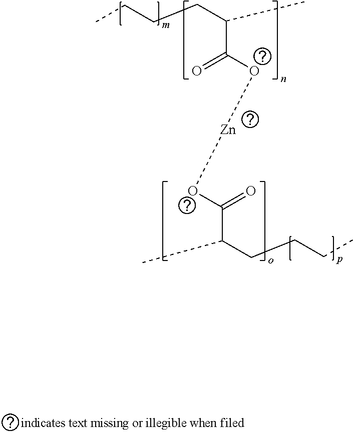

With the invented layer structure, the at least one ionomer interlayer film is arranged between the encapsulation layer and the solar cell array. With the glassy state at room temperature, the ionomer interlayer film can be fully fused with and adhere to the crystalline silicon solar cell, and provide a mechanical strength over 100 times higher than traditional encapsulation materials such as EVA and polyvinyl acetate. As the silicon solar cell is bent, the ionomer interlayer films will be forced to bend correspondingly. In this case, the stress will not be concentrated on the bent cell due to the difference of coefficient of elasticity between the ionomer interlayer film and the cell, thereby avoiding the cracking of the solar cell and improving the bending resistance.

Beside ionomers as interlayer films it is also possible to use a combination of an ionomer (e.g. SentryGlas® plus) and a plasticized PVB (e.g. Saflex® (DG)) as multilayer to built up the interlayer film. Especially the usage of DG is advantageous for high latitude and low temperature areas.

Preferably, the encapsulation layer is one of EVA, POE or PVB.

Preferably, the front panel is a transparent PET polymer panel.

Preferably, the rear panel is a PET polymer panel.

The manufacturing method for the flexible crystalline silicon photovoltaic module includes the following steps:
Step 1: connecting a plurality of solar cells in series to form a solar cell array;
Step 2: stacking the front panel, the encapsulation layer and the ionomer interlayer film in turn from bottom to top, placing the solar cell array on the ionomer interlayer film with a light receiving side of the solar cell array facing down, placing the ionomer interlayer film and the encapsulation layer, and finally placing the rear panel;
Step 3: putting stacked parts into a laminator with a lamination temperature of 140-150° C., a vacuuming time of 6-7 min, a downward pressure of −10 to −30 kPa and a time delay of 700-900 s to complete the hot laminating process; and
Step 4: taking out the module to complete the manufacturing process.

Preferably, in step 3, the laminator is set as follows: lamination temperature: 145° C., vacuuming time: 6 min, downward pressure: −20 kPa, time delay: 800 s.

The above steps can be done by traditional photovoltaic production equipment based on the same production process, in which case the equipment may not be upgraded. The ionomer interlayer film is laminated with the encapsulation layer to wrap the solar cell array, in which the encapsulation layer provides good impact buffer and adheres to the front panel and the rear panel, and thus reveals a good bridging effect compared with the practice that the ionomer interlayer film adheres to the front panel and the rear panel directly.

### BRIEF DESCRIPTION OF THE DRAWINGS

FIG. 1 is an exploded view of the structure of the present invention.

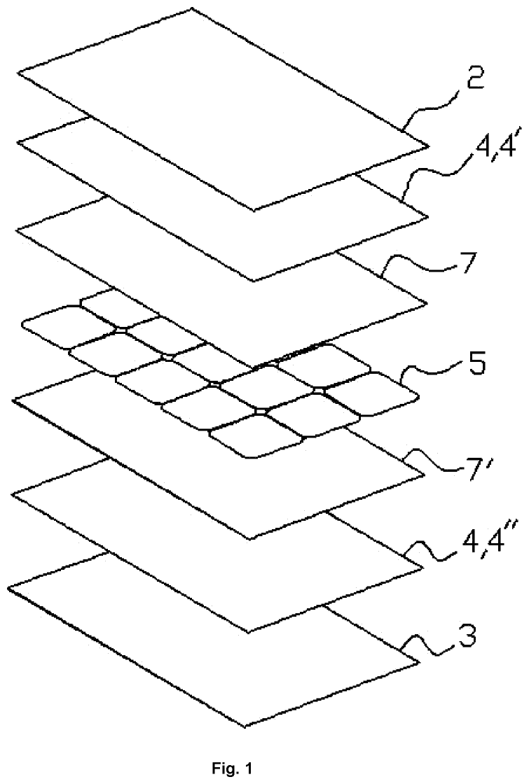

FIG. 2 is an exploded view of the structure in prior art.

FIG. 3 illustrates the cracking of the solar cell with the structure in prior art.

### DETAILED DESCRIPTION OF THE PREFERRED EMBODIMENTS

The present invention will be further described in combination with drawings and embodiments.

Example 1: A flexible crystalline silicon photovoltaic module includes a front panel 2 made of a transparent PET polymer, a rear panel 3 made of a PET polymer panel, an encapsulation layer 4 made of EVA and a solar cell array 5; the front panel 2 and the rear panel 3 are respectively arranged outside the encapsulation layer 4, on which an upper surface and a lower surface of the solar cell array 5 are laminated; and ionomer interlayer films 7 and 7′ are arranged between the encapsulation layer 4 and the solar cell array 5.

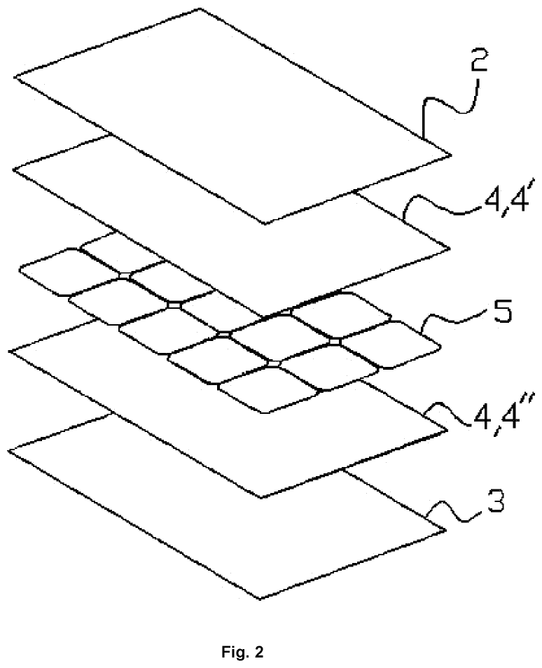

Based on a traditional module shown in FIG. 2, the ionomer interlayer films 7 and 7′ are arranged between the original encapsulation layer 4 and the solar cell array 5, wherein the ionomer interlayer film 7′ may be omitted depending on the service condition of the module; for example, under the condition that no back impact exists, it is allowable to omit the ionomer interlayer film 7′ and reserve the ionomer interlayer film 7 only.

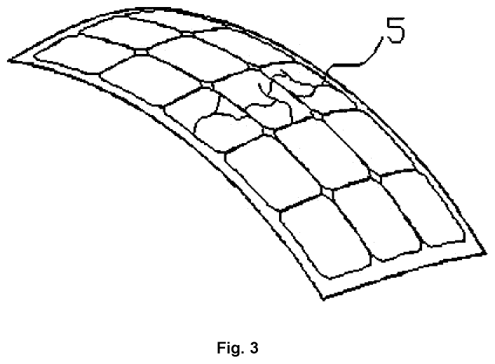

The reason why the ionomer interlayer films 7 and 7′ are used on the crystalline silicon solar cell is as follows: with the glassy state at room temperature, the ionomer interlayer films 7 and 7′ can be fully fused with and adhere to the crystalline silicon solar cell, and provide a mechanical strength over 100 times higher than traditional encapsulation materials such as EVA and polyvinyl acetate; as the crystalline silicon solar cell is bent, the ionomer interlayer films 7 and 7′ will be forced to bend correspondingly; in this case, the stress will not be concentrated on the bent cell due to the difference of coefficient of elasticity between the ionomer interlayer film and the cell, thereby avoiding the cracking of the solar cell, as shown in FIG. 3.

The manufacturing method for the flexible crystalline silicon photovoltaic module in Example 1 includes the following steps:
Step 1: connecting a plurality of solar cells in series to form a solar cell array 5;
Step 2: stacking the front panel 2, the encapsulation layer 4, 4′ and the ionomer interlayer film 7 in turn from bottom to top, placing the solar cell array 5 on the ionomer interlayer film 7 with a light receiving side of the solar cell array 5 facing down, placing the ionomer interlayer film 7′ and the encapsulation layer 4, 4″, and finally placing the rear panel 3;
Step 3: putting stacked parts into a laminator with a lamination temperature of 140-150° C., a vacuuming time of 6-7 min, a downward pressure of −10 to −30 kPa and a time delay of 700-900 s to complete the hot laminating process; and
Step 4: taking out the module to complete the manufacturing process.

The above steps can be done by traditional photovoltaic production equipment based on the same production process, in which case the equipment may not be upgraded.

The encapsulation layers 4 above and below the ionomer interlayer films 7 and 7′ are also indispensable structural layers based on the following reasons: the ionomer interlayer films 7 and 7′ are fused with the cell at room temperature to form a glassy state, and will burst when impacted by a large external force; in this case, the encapsulation layers 4 above and below the ionomer interlayer films provide a good shock buffer; moreover, the ionomer interlayer films 7 and 7′ are poorly adhered to the front panel 2 and the rear panel 3; in contrast, the encapsulation layer 4 may provide good adhesion to bridge the ionomer interlayer films 7 and 7′ with the front panel 2 and the rear panel 3, thereby forming a stable structure with good weather resistance.

Therefore, the crystalline silicon photovoltaic module has the advantage of high conversion efficiency, while the thin film photovoltaic module has the advantage of good flexibility. Based on this structure and process, the crystalline silicon photovoltaic module can combine the advantages of high conversion efficiency and flexibility. This structure and process can help to increase the flexibility angle of the crystalline silicon photovoltaic module from the traditional 5-15° to 60°, without generating the cracks of the crystalline silicon cell.

A second manufacturing method for the flexible crystalline silicon photovoltaic module includes all steps of the above described method, except placing the ionomer interlayer film (T′).

A third manufacturing method for the flexible crystalline silicon photovoltaic module includes all steps of the above described method, except placing the ionomer interlayer film (7).

1. A flexible crystalline silicon photovoltaic module, comprising a front panel, a rear panel, an encapsulation layer and a solar cell array, the front panel and the rear panel being respectively arranged outside the encapsulation layer, on which an upper surface and a lower surface of the solar cell array are laminated, characterized in that at least one ionomer interlayer film is arranged between the encapsulation layer and the solar cell array, characterized in that the at least one ionomer interlayer film has shear modulus G and Young's modulus E values according to the following tables:
shear modulus G [MPa]

| | load duration | | | | | | |
|---|---|---|---|---|---|---|---|
| temperature | 1 s | 3 s | 1 min | 1 hr | 1 day | 1 mo | 10 yrs |
| 10° C. | 240. | 236. | 225. | 206. | 190. | 171. | 153. |
| 20° C. | 217. | 211. | 195. | 169. | 146. | 112. | 86.6 |
| 24° C. | 200. | 193. | 173. | 142. | 111. | 73.2 | 43.3 |
| 30° C. | 151. | 141. | 110. | 59.9 | 49.7 | 11.6 | 5.31 |
| 40° C. | 77.0 | 63.0 | 30.7 | 9.28 | 4.54 | 3.29 | 2.95 |
| 50° C. | 36.2 | 26.4 | 11.3 | 4.20 | 2.82 | 2.18 | 2.00 |
| 60° C. | 11.8 | 8.18 | 3.64 | 1.70 | 1.29 | 1.08 | 0.97 |
| 70° C. | 3.77 | 2.93 | 1.88 | 0.84 | 0.59 | 0.48 | 0.45 |
| 80° C. | 1.55 | 1.32 | 0.83 | 0.32 | 0.25 | 0.21 | 0.18 |

Young's modulus E [MPa]

| | load duration | | | | | | |
|---|---|---|---|---|---|---|---|
| temperature | 1 s | 3 s | 1 min | 1 hr | 1 day | 1 mo | 10 yrs |
| 10° C. | 692. | 681. | 651. | 597. | 553. | 499. | 448. |
| 20° C. | 628. | 612. | 567. | 493. | 428. | 330. | 256. |
| 24° C. | 581. | 561. | 505. | 416. | 327. | 217. | 129. |
| 30° C. | 442. | 413. | 324. | 178. | 148. | 34.7 | 15.9 |
| 40° C. | 228. | 187. | 91.6 | 27.8 | 13.6 | 9.86 | 8.84 |
| 50° C. | 108. | 78.8 | 33.8 | 12.6 | 8.45 | 6.54 | 6.00 |
| 60° C. | 35.3 | 24.5 | 10.9 | 5.10 | 3.87 | 3.24 | 2.91 |
| 70° C. | 11.3 | 8.78 | 5.64 | 2.52 | 1.77 | 1.44 | 1.35 |
| 80° C. | 4.65 | 3.96 | 2.49 | 0.96 | 0.75 | 0.63 | 0.54 |

where the shear modulus G and Young's modulus E values are in a range+/−5% from the values inside the tables.

2. The flexible crystalline silicon photovoltaic module according to claim 1, characterized in that the at least one ionomer interlayer film is arranged on the upper surface of the solar cell array or the lower surface of the solar cell array.

3. The flexible crystalline silicon photovoltaic module according to claim 1, characterized in that two ionomer interlayer films are arranged between the encapsulation layer and the solar cell array where one of these two ionomer interlayer films is arranged on the upper surface of the solar cell array and the other ionomer interlayer films is arranged on the lower surface of the solar cell array.

4. The flexible crystalline silicon photovoltaic module according to claim 1, characterized in that the ionomer interlayer films have a film thickness in the range of 0.3 mm to 3.0 mm.

5. The flexible crystalline silicon photovoltaic module according to claim 1, characterized in that the encapsulation layer is built up by two sublayers where one of these sublayers is arranged on the upper surface of the solar cell array and the other sublayer is arranged on the lower surface of the solar cell array.

6. The flexible crystalline silicon photovoltaic module according to claim 1, characterized in that the encapsulation layer is one of EVA, POE or PVB.

7. The flexible crystalline silicon photovoltaic module according to claim 1, characterized in that the front panel is a transparent PET polymer panel.

8. The flexible crystalline silicon photovoltaic module according to claim 1, characterized in that the rear panel is a PET polymer panel.

9. A method of manufacturing a flexible crystalline silicon photovoltaic module, characterized by comprising the following steps:
Step 1: connecting a plurality of solar cells in series to form a solar cell array;
Step 2: stacking the front panel, the encapsulation layer and the ionomer interlayer film in turn from bottom to top, placing the solar cell array on the ionomer interlayer film with a light receiving side of the solar cell array facing down, placing the ionomer interlayer film and the encapsulation layer, and finally placing the rear panel;
Step 3: putting stacked parts into a laminator with a lamination temperature of 130-160° C., a vacuuming time of 5-10 min, a downward pressure of −10 to −40 kPa and a time delay of 500-1000 s to complete the hot laminating process; and
Step 4: taking out the module to complete the manufacturing process.

10. A method of manufacturing a flexible crystalline silicon photovoltaic module, characterized by comprising the following steps:
Step 1: connecting a plurality of solar cells in series to form a solar cell array;
Step 2: stacking the front panel, the encapsulation layer and the ionomer interlayer film in turn from bottom to top, placing the solar cell array (5) on the ionomer interlayer film with a light receiving side of the solar cell array (5) facing down, placing the encapsulation layer, and finally placing the rear panel;
Step 3: putting stacked parts into a laminator with a lamination temperature of 130-160° C., a vacuuming time of 5-10 min, a downward pressure of −10 to −40 kPa and a time delay of 500-1000 s to complete the hot laminating process; and
Step 4: taking out the module to complete the manufacturing process.

11. A method of manufacturing a flexible crystalline silicon photovoltaic module, characterized by comprising the following steps:
Step 1: connecting a plurality of solar cells in series to form a solar cell array;
Step 2: stacking the front panel and the encapsulation layer in turn from bottom to top, placing the solar cell array on the encapsulation layer with a light receiving side of the solar cell array facing down, placing the ionomer interlayer film and the encapsulation layer, and finally placing the rear panel;
Step 3: putting stacked parts into a laminator with a lamination temperature of 130-160° C., a vacuuming time of 5-10 min, a downward pressure of −10 to −40 kPa and a time delay of 500-1000 s to complete the hot laminating process; and
Step 4: taking out the module to complete the manufacturing process.

12. The method of claim 9, characterized in that in step 3, the laminator is set as follows: lamination temperature: 140-150° C., vacuuming time: 6-7 min, downward pressure: −10 to −30 kPa, time delay: 700-900 s.

13. The method of claim 10, characterized in that in step 3, the laminator is set as follows: lamination temperature: 140-150° C., vacuuming time: 6-7 min, downward pressure: −10 to −30 kPa, time delay: 700-900 s.

14. The method of claim 11, characterized in that in step 3, the laminator is set as follows: lamination temperature: 140-150° C., vacuuming time: 6-7 min, downward pressure: −10 to −30 kPa, time delay: 700-900 s.

15. The flexible crystalline silicon photovoltaic module according to claim 1, wherein the shear modulus G and Young's modulus E values are in a range+/−2.5% from the values inside the tables.
